(19) United States
(12) Patent Application Publication
(10) Pub. No.: US 2023/0103191 A1
(43) Pub. Date: Mar. 30, 2023

(54) REVERSE-CONDUCTING IGBT DEVICE AND MANUFACTURING METHOD THEREOF, INVERTER STAGE

(71) Applicant: STMICROELECTRONICS S.r.l., Agrate Brianza (IT)

(72) Inventors: Ignazio BERTUGLIA, Catania (IT); Ettore CHIACCHIO, Catania (IT)

(73) Assignee: STMICROELECTRONICS S.r.l., Agrate Brianza (IT)

(21) Appl. No.: 17/947,703

(22) Filed: Sep. 19, 2022

(30) Foreign Application Priority Data
Sep. 29, 2021 (IT) 102021000024974

(51) Int. Cl. H01L 29/872; H01L 29/739; H01L 29/06; H02M 7/537; H01L 21/265

(52) U.S. Cl. CPC H01L 29/872; H01L 29/7397; H01L 29/0696; H02M 7/537; H01L 21/26513

(57) ABSTRACT

A RC-IGBT with fast recovery integrated diode is proposed adopting the concept of a hybrid structure with conventional IGBT emitter trench-stop, separated from an embedded low efficiency injection anode diode. The body region of the IGBT and the anode region of the diode are separately patterned and doped, and the metal barrier layer is removed from the diode area allowing a direct ohmic contact of AlSi alloy on the underneath P-doped anode. A full-anode contact opening is present in the diode area. Moreover, corresponding dummy trenches in the diode area are short-circuited to the emitter electrode giving the benefit to reduce the transfer Miller capacitance. In this way, a good trade-off of VF vs Err can be obtained for the integrated diode without downgrading the IGBT performances both in terms of VCEsat and leakage, differently from the case of devices manufactured by lifetime control techniques.

### BACKGROUND

### Technical Field

The present disclosure relates to a reverse-conducting IGBT (RC-IGBT) device and to a manufacturing method thereof. The present disclosure further relates to an inverter stage including a plurality of RC-IGBT devices. The RC-IGBT includes a vertical-conduction IGBT device and a diode (for example a Freewheeling Diode, FWD), which are integrated in a same die side by side. The present disclosure further relates to a system including a plurality of RC-IGBT devices.

### Description of the Related Art

In a variety of applications where the IGBT (Insulated-Gate Bipolar Transistor) device is used as a switch on an inductive load, a connection with an anti-parallel freewheeling diode is needed to prevent potentially damaging and sudden voltage spikes. The provision of separate chips, one housing the IGBT and the other housing the diode, is normally the preferred solution in all the cases where a certain (good) trade-off between static and dynamic performance is requested. At the same time, integrated solutions (i.e., reverse conducting IGBT, RC-IGBT) can be considered among the preferred choices for reducing costs and dimensions. Moreover, RC-IGBT can show performances that are comparable, under soft switching conditions, with those of discrete configurations including an IGBT connected to the external diode. These solutions are becoming more and more appreciated for induction heating application.

RC-IGBT integrating the diode and the IGBT in a single chip offer cost saving and further package miniaturization as main benefits. Limitations of these solutions include the not optimized reverse recovery performance of the built-in diode, confining their usage essentially in the induction cookers or motor control application with low current rating and soft switching regime. Lifetime control techniques are commonly adopted in order to reduce the reverse-recovery current Irr (and the reverse-recovery charge Qrr as well as the reverse-recovery time Trr) but with a negative feedback on the IGBT side. Alternatively, reduced doping of P+deep body layer has been proposed, but at the expense of the anti- latch robustness, which is negatively affected.

Nowadays, the most common approach to optimize reverse recovery of the built-in diode in the RC-IGBT is the adoption of a lifetime control technique (beta electron irradiation, platinum diffusion). Unfortunately, this method partially downgrades the performances of the IGBT, where higher conduction loss and leakage increase are the main drawbacks. Moreover, for the platinum case, the temperature coefficient of the VCEsat (Collector-Emitter saturation voltage) of the IGBT and of the VF (forward voltage) of the diode can undesirably increase for the high current levels, making these devices unfit for high-power motor control application where a plurality of devices in parallel connection are required (e.g., inverter modules).

An alternative approach, with less impact on the IGBT, is based on the design of a diode structure separate from that of the IGBT, and to the adoption, only for the diode, of one of the several known structures that are basically based on the principle of low efficiency injection anode. Nevertheless, the metallization present at the front side of the IGBT, plus the barrier metal, does not work properly as promoter of an ohmic contact on low P-doped layer. This scenario results in the formation of Schottky contact on the diode anode causing huge spread of VF. Theoretically, it could be adopted an enrichment process of the anode contact by means of P+ shallow implants, but actually it is not possible to match the appropriate P+ dose to achieve, at the same time, a good ohmic contact and a good trade-off of the VF vs the Qrr when a barrier metal is interposed. RC-IGBT with an integrated Schottky-Controlled Injection Diode are further promising structures for optimizing the reverse recovery of the diode. Anode and body regions are not differentiated and no VF spread occurs. Schottky junction is just a little part of device. Drawbacks include the complexity to realize two additional masks (N+ and N cathode regions) on the back side, which are to be aligned to each other and with the geometry/layout at the top side. Moreover, the impact on IGBT performances are still to be fully evaluated.

Finally, another interesting concept is the Reverse Conducting IGBT with Diode Control (RCDC-IGBT). The optimization of reverse recovery is not inherent to a particular internal design, but it is obtained by applying an appropriate patterned desaturation gate signal in the external circuit, which drives the transistor during the forward diode mode conduction just a while before the reverse recovery phase takes place. The drawbacks include the complexity and the cost of the external driving circuit, confining this solution to very high voltage applications like power train traction (3.3 kV or 6.5 kV).

In conclusion, the need is felt for a RC-IGBT and a manufacturing method thereof that overcome the above-mentioned drawbacks and limitations.

### BRIEF SUMMARY

According to the present disclosure, a manufacturing method of the reverse-conducting IGBT device, a reverse-conducting IGBT device, and an inverter stage including a plurality of RC-IGBT devices, are provided.

BRIEF DESCRIPTION OF THE SEVERAL VIEWS OF THE DRAWINGS

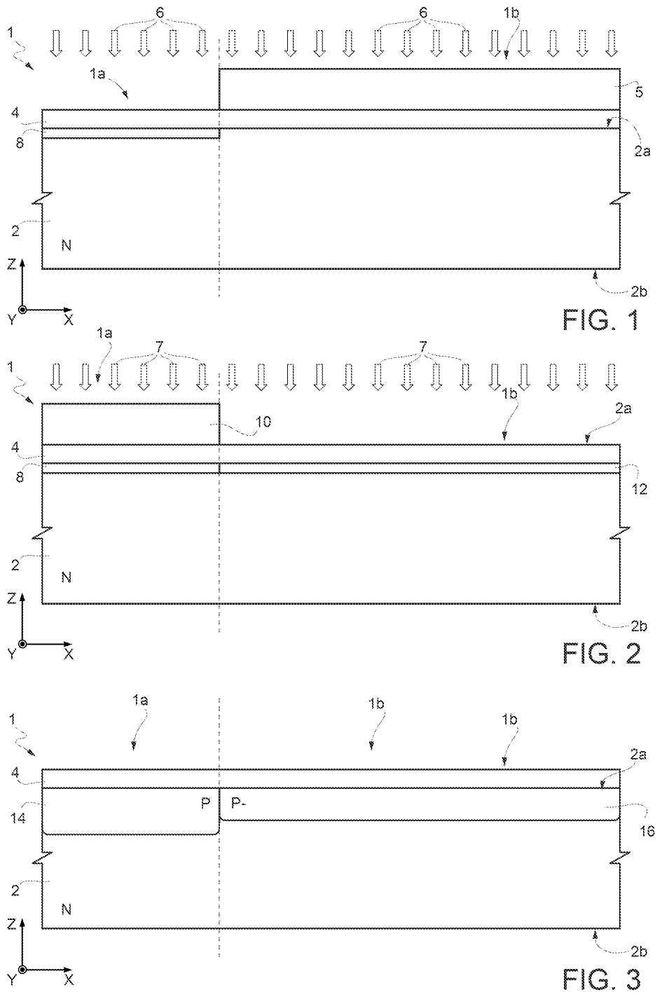

For a better understanding of the disclosure, embodiments thereof are now described, purely by way of non-limiting example and with reference to the attached drawings, wherein: FIGS. 1-15 show cross-section views of a RC-IGBT device during subsequent manufacturing steps, according to the present disclosure; and

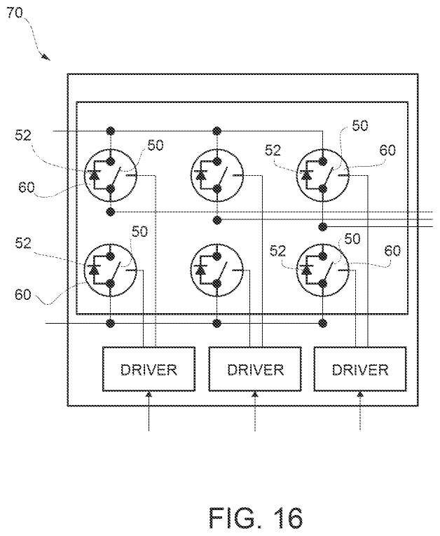

FIG. 16 is a schematic representation of a system (an inverter stage) including a plurality of RC-IGBT devices according to the present disclosure.

### DETAILED DESCRIPTION

To summarize aspects of the present disclosure (without limiting the present disclosure thereto), a reverse conducting IGBT (RC-IGBT) with fast recovery integrated diode is proposed to include a hybrid structure with an IGBT emitter trench-stop, separated from an embedded low efficiency injection anode diode. The body region of the IGBT and the anode region of the diode are separately patterned and doped, and the metal barrier layer is removed from the diode area allowing a direct ohmic contact of AlSi alloy on the underneath P-doped anode. A “full-anode” contact opening is present in the diode area. Moreover, corresponding dummy trenches in the diode area are short-circuited to the emitter electrode giving the benefit to reduce the transfer Miller capacitance. In this way, a good trade-off of VF (forward voltage) vs Err (reverse recovery energy) can be obtained for the integrated diode without downgrading the IGBT performances both in terms of VCEsat and leakage, differently from the case of devices manufactured by lifetime control techniques.

The present disclosure is described with reference to FIGS. 1-15, which show a cross-sectional view of a portion of a wafer 1 during subsequent manufacturing steps of a manufacturing process. The figures show the wafer 1 in a triaxial system of mutually orthogonal axes X, Y, Z (Cartesian system).

With reference to FIG. 1, the wafer 1 is provided or arranged (only a portion is shown). The wafer 1 includes a first sub-portion 1a and a second sub-portion 1b, which are arranged, or extended, next to one another without physical interruption.

The first subportion 1a is designed to house, at least in part, an IGBT device, while the second sub-portion 1b is designed to house, at least in part, a diode device.

The wafer 1 includes a semiconductor substrate 2, for example, an N-type doped floating-zone silicon substrate having a resistivity designed according to a required maximum V_{CE} blocking voltage. The substrate 2 has a top surface 2a opposed to a bottom surface 2b along the direction of the Z-axis.

With the term “substrate,” the present disclosure refers to any solid body including a base substrate only or a base substrate with one or more epitaxially grown layers of semiconductor material on it.

A pre-implant mask 4 is formed on a top surface 2a of the substrate 2. The pre-implant mask 4, which is for example thermal Silicon Oxide (SiO₂), has a suitable thickness in the range below 100 nm.

A photoresist mask 5 is then formed on the pre-implant oxide 4 and patterned in order to cover the second sub-region lb and leave open, or exposed, the first sub-region 1a.

An implant step is then carried out (illustrated in FIG. 1 by arrows 6) to implant dopant species of a P conductivity type that, in further manufacturing steps, will form a body region of the IGBT device. An implanted P-type region 8 is thus formed in the substrate 2, facing the top surface 2a. Implant species may include for example Boron, with an implant dose in the order of 10¹³ ions/cm².

Then, FIG. 2, the photoresist mask 5 is removed and a new photoresist mask 10 is formed on the pre-implant mask 4 at the second sub-portion 1b side. The photoresist mask 10 covers the first sub-portion 1a and leaves open, or exposed, the second-sub-portion 1b.

An implant step (illustrated by arrows 7) is then carried out to form an implanted region 12 in the substrate 2 at the second sub-region 1b, to form, as better understood from subsequent steps, an anode region of the diode. The implanted region 12 faces the top surface 2a of the substrate 2.

The implanted region 12 is of P-type conductivity as well as the implanted region 8. Implant species may include again for example Boron, with an implant dose in the order of 10¹² ions/cm², which is one order of magnitude lower than that of the implanted region 8.

Then, FIG. 3, a diffusion step of the implanted regions 8 and 12 is carried out. Diffusion includes thermal treatment of wafer 1 in a reactor (for example furnace) at a temperature of about 1000-1200° C. A highly-doped P-type (P) body region 14 is formed at the sub-region 1a and a low-doped P-type (P−) anode region 16 is formed at the sub-region 1b.

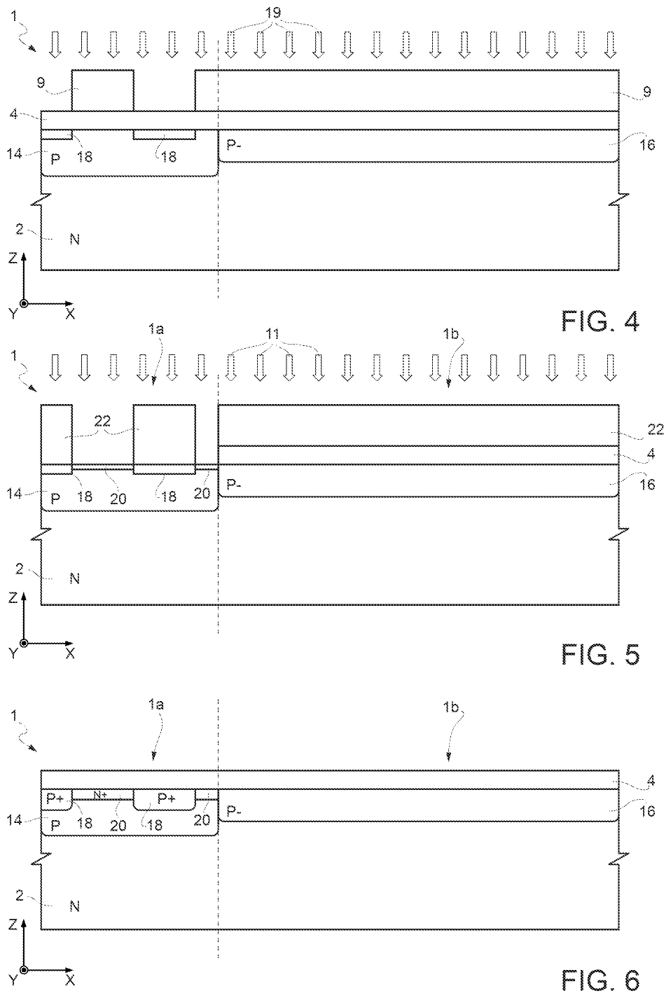

Then, FIG. 4, contact body regions 18 are formed within the body region 14. To this end, a photoresist mask 9 is formed on the pre-implant mask 4, covering the wafer 1 with the exception of the surface regions of the wafer 1 where the contact body regions 18 are to be formed. An implant step of P-type species (e.g., Boron) is carried out, with a dose of around 1·10¹⁵ atoms/cm².

Then, FIG. 5, the pre-implant mask 4 is selectively removed from the first sub-region 1a only, through a masked etching step. Then, source regions 20 of the IGBT are formed by implanting (arrows 11) dopant species of N-type laterally to the contact body regions 18 previously formed. The dose of the N-type species is around 1·10¹⁵ atoms/cm². The source regions 20 extends therefore between the contact body regions 18. A photoresist mask 22 is used during this implant step, leaving uncovered the surface region where the source regions 20 are to be formed.

Then, FIG. 6, the pre-implant mask 4 is formed again at the first sub-region 1a. A diffusion step of the implanted regions 18 and 20 is carried out. The diffusion includes thermal treatment of wafer 1 in a reactor (for example furnace) at a temperature in the order of 1000° C. for a time duration of some hours. The source region 20 has a density peak concentration of doping species in the order of 1·10¹⁹-1·10²⁰ ion/cm³; the contact body region 18 has a density peak concentration of doping species of about 1·10¹⁸-1·10¹⁹ ion/cm³.

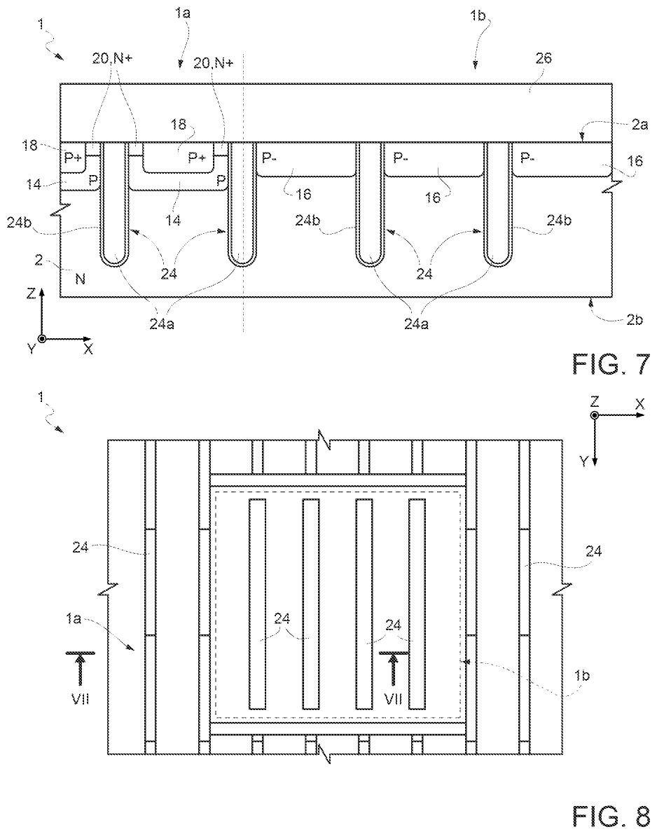

Then, FIG. 7, trenches 24 are formed within the substrate 2. In the first sub-region 1a the trenches 24 are the gate terminal (of a “trench-gate” type) of the IGBT device. In the second sub-region 1b, the trenches 24 are dummy trenches and are electrically connected (for example, short circuited) to the IGBT emitter terminal.

Each of the trenches 24 comprises an inner conductive region 24a surrounded by a respective dielectric layer 24b. The conductive region 24a may be, for example, of metal material, or of doped polysilicon. The gate dielectric layer 24b is, for example, an oxide, such as SiO₂.

Each trench 24 has, by way of example, a depth, measured along the direction Z starting from the top surface 2a, in the order of few microns and a width, measured along the direction X, in the order of the tenths of μm. The distance (also known as pitch) between a trench region 24 and the immediately subsequent (or previous) trench region 24 along the direction X is, for example, comprised in the range of a few μm.

In each trench 24, the dielectric layer 24b completely covers the walls and the bottom of the respective trench 24, so that the conductive region 24a is electrically insulated from the substrate 2 by the dielectric layer 24b. The top side of each conductive region 24a is aligned to the top surface 2a.

In the sub-region 1a, the trenches 24 extend through the body region 14 and the source regions 20 previously formed, so that a resulting plurality of body regions 14 extend within the substrate 2 alongside (along the direction X) of each trench (gate region) 24. Analogously, the trenches 24 extend through the source regions previously formed, thus forming a plurality of source regions 20 that extend in the body regions laterally to the trench gate 24 and, more particularly, between the contact body regions 18 and the trenches 24.

The manufacturing steps for forming the trenches 24 are known in the art. For example, a masked dry etching step is carried out to selectively remove the material of the substrate 2 (and of the pre-implant mask 4 above it), followed by subsequent deposition steps of dielectric or insulating material (e.g., SiO2) for forming the dielectric layers 24b and of conductive material (e.g., doped polysilicon) for completely filling the trenches, to form the conductive region 24a.

A pre-metal dielectric (PMD) layer 26, e.g., of oxide material such as Silicon Oxide, is formed on the top surface 2a of the substrate 2. The PMD layer 26 has a thickness in the micrometer range (e.g., 1-3 μm).

FIG. 8 shows, in a top-plan view (on plane XY), a partial view of the wafer 1 where the layout of the first sub-region 1a and of the second sub-region 1b can be better appreciated. FIG. 7 is a cross sectional view taken along cut line VII-VII of FIG. 8.

As shown in FIG. 8, the second sub-portion 1b, i.e., the area housing the diode, has, in one possible embodiment, a square-like shape and the trenches 24 within the second sub-portion 1b have a rectangular shape with main extension along Y-axis. Each trench 24 is physically separated from the other trenches in the second sub-region 1b and are parallel to one another along the Y-axis. In other words, each trench 24 in the second sub-portion 1b is electrically isolated from the other trenches 24 in the same second sub-portion 1b. More importantly, each trench 24 in the second sub-portion 1b is electrically isolated from the trenches 24 in the first sub-portion 1a.

The first sub-portion 1a surrounds the second subportion 1b on one or more sides (in this example, the first sub-portion 1a completely surrounds the second subportion 1b at all sides). The trenches 24 in the first sub-portion 1a extend parallel to one another along the Y-axis.

In order to bias, during use, the trenches 24 in the second sub-portion 1b and in the first sub-portion 1a, respective biasing lines are provided (e.g., formed at the periphery or outside of the active areas of the IGBT/diode devices), in a per se known way.

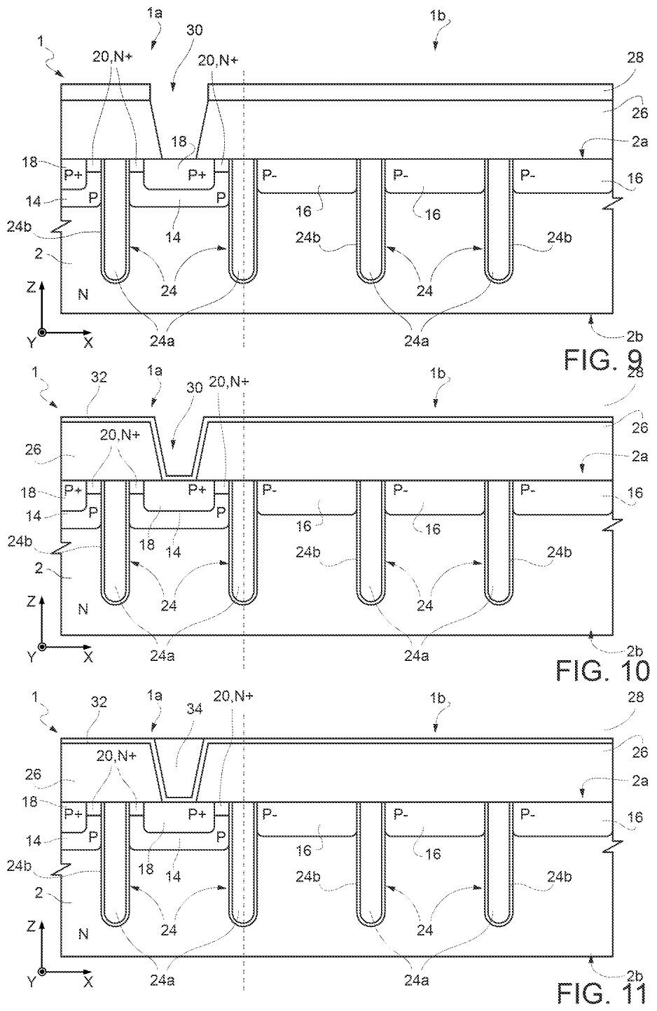

In FIG. 9, a photoresist mask 28 is formed on the PMD layer 26, in order to open, by means of an etching step, a contact hole 30 above the body region 14 (for example above the contact body region 18), to provide an aperture through which the body region can be electrically contacted. The top surface 2a of the substrate 2 is exposed through the hole 30.

Then, FIG. 10, the mask 28 is removed and a deposition of a barrier layer 32 is carried out within the contact hole 30, on the body region 14 (for example on the contact body region 18) and above the PMD layer 26. The barrier layer 32 is for example a bilayer of Titanium—Titanium Nitride (TiTiN), which is used as a diffusion barrier and adhesion layer for CVD tungsten-filled contacts and vias. The barrier 32 is, in general terms, configured to prevent diffusion of Al and Cu within the substrate 2. Other materials can be used for the barrier layer 32, such as Ti Silicide, TiW.

Then, FIG. 11, a metal deposition, for example, Tungsten (W) deposition, is carried out, to fill the contact hole 30 with a conductive plug 34. Metal filling of hole 30 can be achieved by Chemical Vapor Deposition or Electrochemical Deposition.

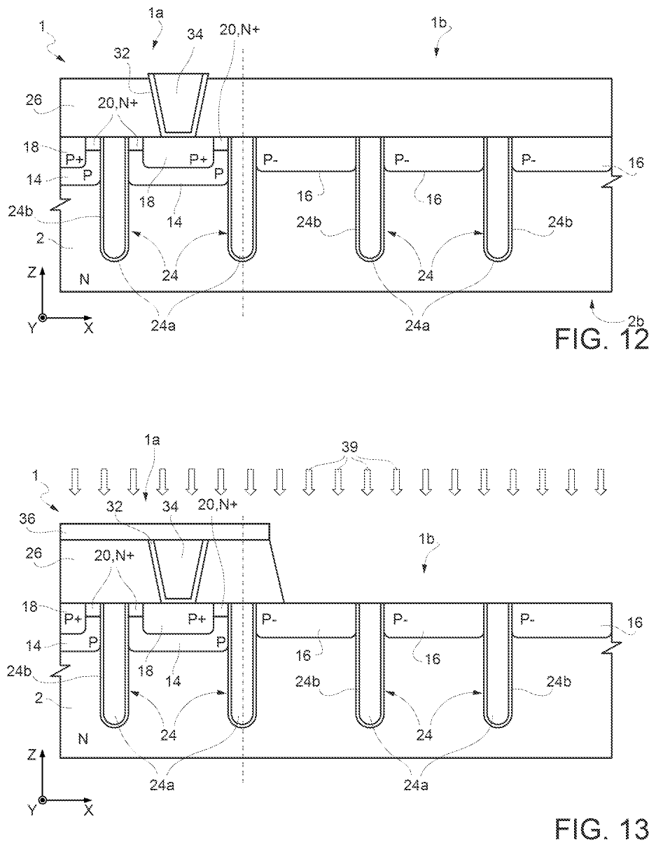

Then, FIG. 12, the barrier layer 32 is removed from the wafer 1 with the exception of the portion of barrier layer 32 extending within the contact hole 30. This step can be carried out via a plasma etch (with or without a dedicated mask) or via a controlled acid wet etch.

With reference to FIG. 13, the PMD layer 26 is removed from the second-sub-portion 1b, at least where anode contacts are to be formed. This step is carried out through a masked etching (e.g., using a photoresist mask 36 that protects the first sub-portion 1a only, and carrying out a wet etching based on HF in case of PMD layer 26 made of Silicon Oxide).

The PMD layer 26 is completely removed from the area where anode contacts are to be formed, in sub-region lb. This patterning step of the PMD layer 26 enables optimized (precise) contact opening in the diode area lb and hence enhances the VF (forward voltage) performances.

A step of contact enrichment in the second sub-portion 1b is carried out, by implanting dopant species of P-type (as represented by arrows 39). The implant dose for enrichment can be modulated in the range of 1.10¹³ atoms/cm² accordingly to the required VF vs. Qrr trade-off.

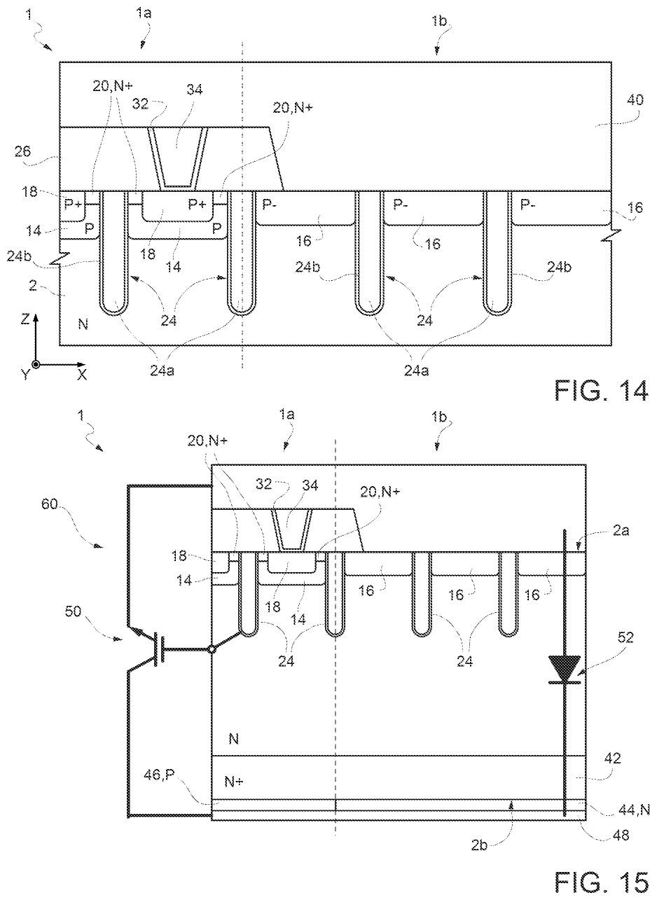

Then, FIG. 14, a layer of metal material 40, for example, a metal alloy including Aluminum and Silicon, is formed on the wafer 1, for example on the conductive plug 34, e.g., in direct electrical contact with the plug 34, and on the doped anode regions 16 of the diode, for example in direct electrical contact with the doped anode regions 16.

The metal layer 40 is for example of AlSiCu or AlSi.

The metal layer 40 directly contacts the Silicon substrate 2 over the low-doped anode region 16, and thanks to the absence of the TiTiN barrier in the second sub-region 1b any Schottky contact is prevented. This results in an improved VF vs Qrr trade-off.

The manufacturing process comprises further steps of Back-End-Of-Line (BEOL), shown in FIG. 15, and including, in a per se known way, the formation of a N-type buffer region 42 at the bottom side 2b of the substrate 2; a N-type cathode region 44 at the bottom side 2b of the substrate 2, on the buffer layer 42, and aligned to the second sub-region 1b only; a P-type emitter region 46 at the bottom side 2b of the substrate 2, on the buffer layer 42, and aligned to the first sub-region la only; and a bottom metal layer 48 that electrically contacts both the P-type emitter region 46 and the N-type cathode region 44.

A RC-IGBT device 60, including an IGBT device 50 and a diode device 52 integrated in a same die, are thus formed, as represented by the IGBT and diode symbols in FIG. 15.

The electronic device of FIG. 15 is known as reverse-conducting IGBT (RC-IGBT), which integrates an IGBT and a freewheeling diode (FWD) on a single chip. In many IGBT applications, there is a mode in which freewheeling current flows from the emitter to the collector. For this freewheeling operation, the freewheeling diode is connected anti-parallel to the IGBT.

The P-emitter region 46 is the emitter of the PNP parasitic bipolar transistor that is present in the IGBT structure. The corresponding terminal at the bottom metal layer 48 is the collector terminal of the IGBT 50 (the emitter terminal of the IGBT being at the top metal 40).

With reference to the RC-IGBT device 60, the bottom metal 48 (collector) electrically connects in short circuit the P-emitter region 46 of the parasitic bipolar transistor with the N+region 44 of the cathode of the diode 52, allowing the reverse conduction of the integrated diode 52. The electrical parameter that defines the direct voltage drop of the diode is the VFEC (Voltage Forward between Emitter and Collector terminals).

A step of dicing (not shown) is then performed on the wafer 1, to cut a plurality of dies each housing at least an IGBT device 51 integrated with at least a diode device 52.

FIG. 16 is a schematic representation of a system 70 where the die or chip including a plurality of RC-IGBT devices 60 (each of them comprising the IGBT device 50 and the diode device 52) can be used. The system 70 is an inverter circuit.

Known inverter systems use a plurality of power transistor devices (such as PMOS or SiCMOS or IGBT).

The RC-IGBT device 60 of the present disclosure may, in one exemplary motor control application, replace the known IGBT discrete solution with external freewheeling diode (FWD), allowing both cost reduction and further miniaturization capability of power modules even at higher power rates.

The present disclosure can also find application in induction heating appliances.

The advantages afforded by the present disclosure emerge clearly from the foregoing description.

The electronic component of the present disclosure has improved reverse recovery performances, improved VF vs Qrr trade-off, positive thermal coefficients for VCEsat and VF (desirable for paralleling at higher current rates), a Tjₘₐₓ>175C thanks to very low leakage current (where Tjₘₐₓ is the maximum temperature of the junction under operative mode), and the absence of negative impact on IGBT VCE_{SAT}.

Moreover, it is noted that not using any “lifetime-killing techniques” helps to prevent the leakage, especially at high temperature.

Other advantages include:
absence of multiple masks on the back side: just one to implant cathode enrichment;
no need for complex and expensive driving circuitry (conventional driving circuit can be used);
full feasibility of the proposed process flow from the manufacturing point of view;
no needing for new or huge investments to adapt the currently available semiconductor factories;
optimization of contact resistance in the diode portion by the selective removal of the TiTiN barrier, which allows to adopt low injection anode structure in a very efficient way.

A method for manufacturing a reverse-conducting IGBT, RC-IGBT, device (60), may be summarized as including the steps of forming, in a first region (1a) of a semiconductor substrate (2) having a first conductivity type (N), a IGBT (50), including forming, at a first side (2a) of the semiconductor substrate (2), a body region (14) having a second conductivity type (P) opposite to the first conductivity type (N), forming a source region (20) having the first conductivity type (N) in the body region (14), forming a trench gate (24) through the body region (14); forming, in a second region (1b) of the semiconductor substrate (2), a diode (52), including forming, at the first side (2a) of the semiconductor substrate (2), an anode region (16) having the second conductivity type (P), characterized in that the method further includes the steps of forming, on the first side (2a) of the semiconductor substrate (2), a structural layer (26); opening, in the structural layer (26), a contact hole (30) reaching the body region (14) at the first side (2a) of the semiconductor substrate (2); filling the contact hole (30) with a barrier layer (32) configured for preventing metal ions diffusion, and with a metal plug (34) on the barrier layer (32); selectively removing the structural layer (26) from the second region (1b), exposing the anode region (16); forming on, and in electrical contact with, the anode region (16) and the metal plug (34), a first electrical terminal (40) of the RC-IGBT device (60), said first electrical terminal being of a conductive material including an alloy of Aluminum and Silicon; forming at a second side (2b), opposite to the first side (2a), of the semiconductor substrate (2), a cathode terminal (44) of the diode (52) and an emitter terminal (46) of the IGBT (50); and forming on, and in electrical contact with, the cathode terminal (44) and the emitter terminal (46) a second electrical terminal (48) of the RC-IGBT device (60).

The metal plug (34) may be of Tungsten, and the first electrical terminal (40) may be of AlSiCu or AlSi.

The barrier layer (32) may be of TiTiN, or Ti Silicide, or TiW.

The structural layer (26) may be of dielectric material.

The first electrical terminal (48) may be the collector terminal of the IGBT (50) and the cathode terminal of the diode (52); and the second electrical terminal (40) may be the emitter terminal of the IGBT (50) and the anode terminal of the diode (52).

The IGBT (50) and the diode (52) may be connected to one another in anti-parallel configuration.

The steps of forming the body region (14) and the source region (20) may be carried out using respective implant masks (5, 9, 22) at the second region (1b) configured to entirely cover and protect the second region (1b).

The step of forming the anode region (16) may be carried out with a respective implant mask (10) at the first region (1a) configured to entirely cover and protect the first region (1b).

The step of filling the contact hole (30) with a barrier layer (32) may include depositing a barrier material on the structural layer (26) and within the contact hole (30) and, after having deposited the metal plug (34), carrying out an unmasked etching step using an etching chemical configured to selectively remove the exposed barrier material.

The method may further include, after the step of selectively removing the structural layer (26), the step of forming an enrichment region at the anode region (16) by implanting dopant species of the second conductivity type (P).

The method may further include, after the step of forming the body region (14), the step of forming a contact region (18) within the body region, wherein said contact region (18) may have the second conductivity type (P) and a dopant concentration higher than the dopant concentration of the body region (14), and wherein the step of forming the contact hole (30) may include forming an aperture through the structural layer (26) on, and at least partially aligned with, said contact region (18).

A reverse-conducting IGBT, RC-IGBT, device (60), may be summarized as including a IGBT (50) in a first region (1a) of a semiconductor substrate (2) having a first conductivity type (N), including a body region (14) having a second conductivity type (P) opposite to the first conductivity type (N), facing a first side of the semiconductor substrate (2); a source region (20), having the first conductivity type (N), in the body region (14), a trench gate (24) extending through the body region (14); a diode (52) in a second region (1b) of the semiconductor substrate (2), including an anode region (16), having the second conductivity type (P), facing a first side of the semiconductor substrate (2), characterized in that the RC_IGBT device (60) further includes a structural layer (26) extending on the first side (2a) of the semiconductor substrate (2) at the first region (1b); a contact hole (30) at the first side (2a) of the semiconductor substrate (2) on, and at least partially aligned with, the body region (14); a barrier layer (32) in the contact hole (30), configured for preventing metal ions diffusion; a metal plug (34) in the contact hole (30) on the barrier layer (32); a first electrical terminal (40) of the RC-IGBT device (60) on, and in electrical contact with, the anode region (16) and the metal plug (34), said first electrical terminal being of a conductive material including an alloy of Aluminum and Silicon; a cathode terminal (44) of the diode (52) and an emitter terminal (46) of the IGBT (50) at a second side (2b), opposite to the first side (2a), of the semiconductor substrate (2); and a second electrical terminal (48) of the RC-IGBT device (60) on, and in electrical contact with, the cathode terminal (44) and the emitter terminal (46).

The metal plug (34) may be of Tungsten, and the first electrical terminal (40) may be of AlSiCu or AlSi.

The barrier layer (32) may be of TiTiN, or Ti Silicide, or TiW.

The structural layer (26) may be of dielectric material.

The first electrical terminal (48) may be the collector terminal of the IGBT (50) and the cathode terminal of the diode (52); and the second electrical terminal (40) may be the emitter terminal of the IGBT (50) and the anode terminal of the diode (52).

The IGBT (50) and the diode (52) may be connected to one another in anti-parallel configuration.

The device may further include an enrichment region at the anode region (16) including dopant species of the second conductivity type (P).

The device may further include a contact region (18) within the body region (14), wherein said contact region (18) may have the second conductivity type (P) and a dopant concentration higher than the dopant concentration of the body region (14), and wherein the contact hole (30) may extend through the structural layer (26) on, and at least partially aligned with, said contact region (18).

An inverter (70) stage, may be summarized as including a plurality of RC-IGBT devices.

The various embodiments described above can be combined to provide further embodiments. Aspects of the embodiments can be modified, if necessary to employ concepts of the various embodiments to provide yet further embodiments.

These and other changes can be made to the embodiments in light of the above- detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing a reverse-conducting IGBT device, comprising:
forming, in a first region of a semiconductor substrate having a first conductivity type, an IGBT, wherein the forming the IGBT includes:
forming, at a first side of the semiconductor substrate, a body region having a second conductivity type opposite to the first conductivity type,
forming a source region having the first conductivity type in the body region; and
forming a trench gate through the body region;
forming, in a second region of the semiconductor substrate, a diode, wherein the forming the diode include:
forming, at the first side of the semiconductor substrate, an anode region having the second conductivity type,
forming, on the first side of the semiconductor substrate, a structural layer;
opening, in the structural layer, a contact hole reaching the body region at the first side of the semiconductor substrate;
filling the contact hole with a barrier layer configured to prevent metal ions diffusion, and with a metal plug on the barrier layer;
selectively removing the structural layer from the second region, thereby at least partially exposing the anode region;
forming on the anode region and the metal plug, a first electrical terminal in electrical contact with the anode region and the metal plug, the first electrical terminal being of a conductive material including an alloy of Aluminum and Silicon;
forming on a second side of the semiconductor substrate opposite to the first side a cathode terminal of the diode and an emitter terminal of the IGBT; and
forming on the cathode terminal and the emitter terminal a second electrical terminal in electrical contact with the cathode terminal and the emitter terminal.

2. The method of claim 1, wherein the metal plug is of Tungsten, and the first electrical terminal is of AlSiCu or AlSi.

3. The method of claim 1, wherein the barrier layer is one or more of TiTiN, Ti Silicide, or TiW.

4. The method of claim 1, wherein the structural layer is of a dielectric material.

5. The method of claim 1, wherein:
the first electrical terminal is a collector terminal of the IGBT and an anode terminal of the diode; and
the second electrical terminal is an emitter terminal of the IGBT and a cathode terminal of the diode.

6. The method of claim 1, wherein the IGBT and the diode are connected to one another in anti-parallel configuration.

7. The method of claim 1, wherein the forming the body region and the forming the source region are carried out using respective implant masks on the second region configured to entirely cover and protect the second region.

8. The method of claim 1, wherein the forming the anode region is carried out with a respective implant mask on the first region configured to entirely cover and protect the first region.

9. The method of claim 1, wherein the filling the contact hole with the barrier layer includes:
depositing a barrier material on the structural layer and within the contact hole and,
after having deposited the metal plug, carrying out an unmasked etching step using an etching chemical to selectively remove the exposed barrier material.

10. The method of claim 1, further comprising, after the selectively removing the structural layer, forming an enrichment region at the anode region by implanting dopant species of the second conductivity type.

11. The method of claim 1, further comprising, after the forming the body region, forming a contact region within the body region,
wherein the contact region has the second conductivity type and a dopant concentration higher than a dopant concentration of the body region, and
wherein the forming the contact hole comprises forming an aperture through the structural layer on, and at least partially aligned with, the contact region.

12. A reverse-conducting IGBT device, comprising:
an IGBT in a first region of a semiconductor substrate having a first conductivity type, the IGBT including:
a body region having a second conductivity type opposite to the first conductivity type, the body region adjacent to a first side of the semiconductor substrate;
a source region having the first conductivity type and in the body region; and
a trench gate extending through the body region;
a diode in a second region of the semiconductor substrate, the diode including an anode region adjacent to the first side of the semiconductor substrate, the anode region having the second conductivity type;
a structural layer on the first region;
a contact hole in the structural layer and at least partially aligned with the body region;
a barrier layer in the contact hole, configured to prevent metal ions diffusion;
a metal plug in the contact hole on the barrier layer;
a first electrical terminal on the anode region and the metal plug and in electrical contact with the anode region and the metal plug, the first electrical terminal being of a conductive material including an alloy of Aluminum and Silicon;
a cathode terminal of the diode and an emitter terminal of the IGBT on a second side of the semiconductor substrate that is opposite to the first side; and
a second electrical terminal on the cathode terminal and the emitter terminal and in electrical contact with the cathode terminal and the emitter terminal.

13. The device of claim 12, wherein the metal plug is of Tungsten, and the first electrical terminal is of one or more of AlSiCu or AlSi.

14. The device of claim 12, wherein the barrier layer is one or more of TiTiN, Ti Silicide, or TiW.

15. The device of claim 12, wherein the structural layer is of dielectric material.

16. The device of claim 12, wherein:
the first electrical terminal is the collector terminal of the IGBT and the anode terminal of the diode; and
the second electrical terminal is the emitter terminal of the IGBT and the cathode terminal of the diode.

17. The device of claim 12, wherein the IGBT and the diode are connected to one another in anti-parallel configuration.

18. The device of claim 12, further comprising an enrichment region in the anode region including dopant species of the second conductivity type.

19. The device of claim 12, further comprising a contact region within the body region,
wherein said contact region has the second conductivity type and a dopant concentration higher than a dopant concentration of the body region, and
wherein the contact hole extends through the structural layer and at least partially aligned with the contact region.

20. An inverter stage, including a plurality of reverse conducting IGBT devices, a reverse conducting IGBT of the plurality of reverse conducting IGBT including:
an IGBT in a first region of a semiconductor substrate having a first conductivity type, the IGBT including a body region adjacent to a first side of the semiconductor substrate, the body region having a second conductivity type different from the first conductivity type;
a diode in a second region of the semiconductor substrate, the diode including an anode region adjacent to the first side of the semiconductor substrate, the anode region having the second conductivity type;
a structural layer on the first region, the anode region at least partially offset with respect to the structural layer;
a contact structure in the structural layer and at least partially overlapping and in contact with the body region; and
a first electrical terminal on the anode region and the contact structure and in contact with the anode region and the contact structure.
